(19) United States
(12) Patent Application Publication
(10) Pub. No.: US 2025/0340988 A1
(43) Pub. Date: Nov. 6, 2025

(54) SEMICONDUCTOR APPARATUS FOR GAS MIXING AND METHOD OF FILM DEPOSITION

(71) Applicant: TAIWAN SEMICONDUCTOR MANUFACTURING COMPANY LTD., HSINCHU (TW)

(72) Inventors: JHIH-REN LIN, NEW TAIPEI CITY (TW); YU-TING TSAI, NEW TAIPEI CITY (TW); CHUNG HSIEN LIAO, HSINCHU CITY (TW); JUI-MU CHO, HSINCHU COUNTY (TW)

(21) Appl. No.: 18/654,020

(22) Filed: May 3, 2024

(51) Int. Cl. C23C 16/455; C23C 16/458; H01L 21/02; H01L 21/285

(52) U.S. Cl. CPC C23C 16/45563; C23C 16/4583; H01L 21/02271; H01L 21/28506

(57) ABSTRACT

An apparatus, for performing a film deposition or an etching operation, includes a chamber; a substrate holder, disposed in the chamber, and configured to hold a substrate during the film deposition; a gas dispenser, disposed in the chamber and above the substrate holder; a passage, disposed above and connecting to the gas dispenser, wherein the passage has a curved sidewall; and a first inlet, connecting to the passage for a first gas injection to the gas dispenser, wherein the first inlet includes a first sidewall and a second sidewall opposite to and substantially parallel to the first sidewall, the first sidewall connects the curved sidewall at a first point, the second sidewall connects the curved sidewall at a second point, the first sidewall and a first tangent line at the first point on the curved sidewall is substantially parallel. A method for film deposition or etching operation is also provided.

### BACKGROUND

In recent years, the density is increased in integrated circuit technology since the minimum feature size of lithography has been reduced to below one micrometer. In the fabrication of precision via and contact opening at these reduced dimensions, there is a need to form insulating layers (inter metal dielectric (IMD), interlevel dielectric (ILD) layers) that have uniform wet etch rates so that uniform via and contact opening can be formed.

Processing chambers, such as chemical vapor deposition (CVD) chambers and atomic layer deposition (ALD) chambers, are used to process work pieces, such as semiconductor wafers, light crystal diodes, flat panel displays, or other similar substrates. During processing, a substrate located within the processing chamber is exposed to reactant gases introduced into the chamber and the substrate has a film deposited on it. However, apparatus and elements for introducing gases for deposition may affect a thickness uniformity of the film formed on the substrate.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic diagram of an apparatus of in accordance with some embodiments of the present disclosure.

FIG. 2 is a schematic three-dimensional (3D) diagram of a portion of the apparatus shown in FIG. 1 in accordance with some embodiments of the present disclosure.

FIG. 3 is a schematic top-view perspective of the portion of the apparatus shown in FIG. 2 in accordance with some embodiments of the present disclosure.

FIG. 4 is a schematic top-view perspective of a portion of an apparatus in accordance with some embodiments of the present disclosure.

FIG. 5 is a schematic top-view perspective of a portion of an apparatus in accordance with some embodiments of the present disclosure.

FIG. 6 is a flow diagram of a method for manufacturing a semiconductor structure in accordance with some embodiments of the present disclosure.

FIGS. 7A and 7B are schematic diagrams of a portion of an apparatus during operation in accordance with a comparative embodiment.

FIG. 8 is a schematic diagram showing distribution of gas concentrations of a reactant gas in a passage in accordance with the comparative embodiment of FIGS. 7A and 7B.

FIGS. 9A and 9B are schematic diagrams of a portion of an apparatus during operation in accordance with an embodiment.

FIG. 10 is a schematic diagram showing distribution of gas concentrations of a reactant gas in a passage in accordance with the embodiment of FIGS. 9A and 9B.

FIG. 11 is a schematic line chart showing thickness differences between different points of different films formed by different embodiments.

FIG. 12 is a schematic diagram showing connections between inlets and a passage of the apparatus in accordance with some embodiments of the present disclosure.

FIG. 13 is a flow diagram of a method for manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of time, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A design of an apparatus for gas mixing can affect a uniformity of a film when the apparatus is applied in a deposition operation or a uniformity of etching result when the apparatus is applied in an etching operation. For example, a conduit may connect to a passage in order to inject a reactant gas and mix with another reactant gas. An angle of a conduit connecting to the passage may result in a blocking area, which may result in less cyclone effect and bad disturbing result of two reactant gases. If the reactant gases are not evenly distributed, it may result in high thickness variation of a deposited film or bad etching uniformity.

The present disclosure provides an apparatus including an inlet having both sidewalls contacting a passage of a mixer body. In addition, for a purpose of strong cyclone effect, the inlet has one of the sidewalls being substantially parallel to a tangent line of the contacting point of the inlet on the passage. A strong cyclone effect of different gas flow can be provided in the passage, and therefore a result of mixing different gases can be achieved. Comparing a film deposited on a substrate using the apparatus of the present disclosure with a film formed using another apparatus having the inlets with each of them have only one sidewall contacting the passage, a thickness uniformity across the substrate of the present disclosure can be improved by 60% compared to the other apparatus.

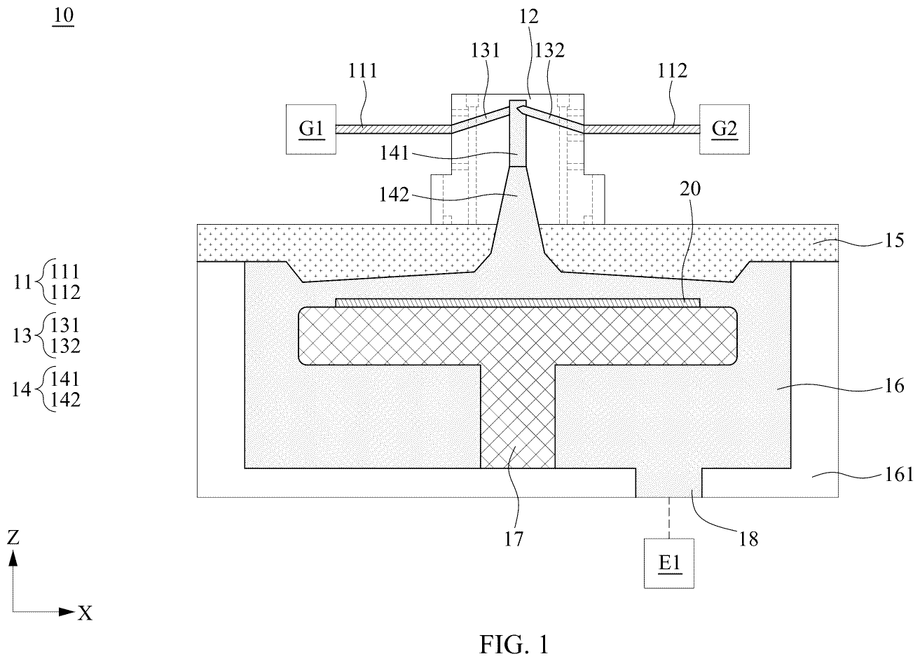

FIG. 1 is a schematic diagram of an apparatus of in accordance with some embodiments of the present disclosure. The apparatus 10 is for performing a semiconductor forming process which requires gas mixing, for example. In some embodiments, the apparatus 10 is for performing an etching operation. In some embodiments, the apparatus 10 is for performing a deposition operation. The apparatus 10 may include a plurality of conduits 11, the mixer body 12, a plurality of inlets 13, a passage 14, a gas dispenser 15, a processing chamber 16, a substrate holder 17, and a purging valve 18.

The plurality of conduits 11 may connect to different gas sources respectively. For example, the plurality of conduits 11 includes a first conduit 111 connecting to a first gas source G1, and a second conduit 112 connecting to a second gas source G2. The first gas source G1 and the second gas source G2 may include different gases, and the first conduits 111 and the second conduits 112 are for introduction of different gases to the processing chamber 16.

The plurality of conduits 11 may connects to the plurality of inlets 13 respectively. The conduits 11 and the inlets 13 can be individually hallow passages, such as a tube, pipe, or conduits. In some embodiments, each of the conduits 11 is disposed between a respective gas source and the mixer body 12. In some embodiments, the inlets 13 are disposed in the mixer body 12, which is disposed over the processing chamber 16. The inlets 13 can be gas inlets or fluid inlets. The plurality of inlets 13 may include a first inlet 131 and a second inlet 132. In some embodiments, the first inlet 131 is disposed between the first conduit 111 and the passage 14. In some embodiments, the first inlet 131 provides gaseous or fluid communication between the first conduit 111 and the passage 14. In some embodiments, one end of the first inlet 131 contacts the first conduit 111 and the other end of the first inlet 131 contacts the passage 14. Similarly, the second inlet 132 can be disposed between the second conduit 112 and the passage 14. In some embodiments, the second inlet 132 provides gaseous or fluid communication between the second conduit 112 and the passage 14. In some embodiments, one end of the second inlet 132 contacts the second conduit 112 and the other end of the second inlet 132 contacts the passage 14.

The passage 14 may be disposed in the mixer body 12 over the gas dispenser 15. In some embodiments, the passage 14 includes an upper portion 141 and a lower portion 142. The upper portion 141 and the lower portion 142 are both hallow structures for gaseous or fluid communication between the inlets 13 and the gas dispenser 15. In some embodiments, the upper portion 141 is disposed over the lower portion 142. In some embodiments, the plurality of inlets connect or contact on an outer sidewall of the upper portion 141 of the passage 14. In some embodiments, the lower portion 142 of the passage connects to the gas dispenser 15. In some embodiments, a diameter of the upper portion 141 is substantially less than or equal to a diameter of the lower portion 142. In some embodiments, the upper portion 141 of the passage 14 has a cylinder configuration. In some embodiments, the upper portion 141 of the passage 14 has a substantially consistent diameter along a vertical direction (e.g., Z direction). In some embodiments, the lower portion 142 has a conical configuration. In some embodiments, diameters of the lower portion 142 increases from the upper portion 141 toward the gas dispenser 15. In some embodiments, an upper end of the lower portion 142 of the passage 14 connects to the upper portion 141, and a lower end of the lower portion 142 of the passage connects to the gas dispenser 15.

The gas dispenser 15 may be disposed in the processing chamber 16 above the substrate holder 17. The gas dispenser 15 includes a showerhead or a funnel lid for introducing the gases from the gas sources G1 and G2 into the processing chamber 16. The gas dispenser 15 is disposed opposite to the substrate holder 17 with respect to a substrate 20 disposed on the substrate holder 17 during operation. In some embodiments, the gas dispenser 15 is connected to at least a gas source (e.g., G1 or G2) and the gas(es) are fed and dispensed into the processing chamber 16 via the gas dispenser 15. The gas dispenser 15 may be made of aluminum or other suitable materials.

One or more gases are introduced into the passage 14 from the gas source(s) G1 and/or G2 through the conduits 11 and the inlet 13. The substrate 20 may be placed on the substrate holder 17 prior to a deposition/etching operation, and one or more gases are introduced into the processing chamber 16 depending on the operation. More than one gases may be transmitted from different gas sources to the processing chamber 16 through respective conduits 11 and respective inlets 13. When more than one gases are introduced concurrently into the passage 14, the gases are mixed in the passage 14 and a downstream gas of the mixed gases is generated and moves toward the substrate 20 through the gas dispenser 15. In some embodiments, the downstream gas facilitates etching of the substrate 20 located on the substrate holder 17 in the processing chamber 16. In some embodiments, the downstream gas facilitates deposition of a thin film on to the substrate 20 located on the substrate holder 17 in the processing chamber 16. The deposition may include chemical vapor deposition (CVD), plasma enhanced CVD (PECVD) processes or high density plasma CVD (HDP-CVD) processes, or atomic layer deposition (ALD) processes to deposit dielectric material layers and/or conductive material layers.

The gas source G1 or G2 includes, for example, oxygen, nitrogen, helium or argon. The downstream gas can include a gas containing a halogen or a halide (e.g., NF₃, CF₄, CHF₃, C₂F₆, C₂HF₅, C₃F₈, C₄F₈, XeF₂, Cl₂ or ClF₃). In some embodiments, the downstream gas include fluorine. In some embodiments, the downstream gas includes H₂, O₂, N₂, Ar, H₂O, and ammonia. In some embodiments, the downstream gas includes one or more gases that comprise metallic materials or semiconductor materials to be deposited on the substrate 20. The metallic or semiconductor materials can include, for example, Si, Ge, Ga, In, As, Sb, Ta, W, Mo, Ti, Hf, Zr, Cu, Sr or Al. In some embodiments, the downstream gas includes one or more gases that comprise metallic or semiconductor materials, or oxides or nitrides comprising the metallic or semiconductor materials. In some embodiments, the downstream gas includes hydrocarbon materials.

The purging valve 18 may be disposed on a lateral sidewall or a lower sidewall of the processing chamber 16. The apparatus 10 may further include an evacuation device E1 to purge the gas(es) in the processing chamber 16. In some embodiments, the purging valve 18 connects to the evacuation device E1. The evacuation device E1 can be, for example, a vacuum pump. The purging valve 18 connecting to evacuation device E1 can facilitate gas flow and direct the downstream gas from the gas dispenser 15 toward the substrate 20. The apparatus 10 may further include an exhaust system (not shown) to exhaust the gas(es) in the processing chamber 16. The exhaust system, for example, may include a purge gas supply, a purge conduit and a vent inlet. The exhaust system can allow flow of the purge gas, such as clean, dry air, atmospheric air or nitrogen or other purge gas through the purge conduit and into the processing chamber 16 for facilitating exhaustion of the reactant gas(es) from the gas source G1 and/or G2.

The substrate holder 17 may be disposed in the processing chamber 16 for holding the substrate 20 thereon. In some embodiments, the substrate holder 17 is referred to as a pedestal. The substrate holder 17 is disposed above a lower sidewall 161 of the chamber 16. The substrate 20 can include a semiconductor substrate, in which the semiconductor substrate is made of, for example, silicon; a compound semiconductor, such as silicon carbide, indium arsenide, or indium phosphide; or an alloy semiconductor, such as silicon germanium carbide, gallium arsenic phosphide, or gallium indium phosphide. The substrate 20 may also include various doped regions, dielectric features, or multilevel interconnects in the semiconductor substrate. The film of dielectric or conductive material is deposited on a surface of the substrate 20 facing the gas dispenser 15. In some embodiments, the substrate holder 17 includes ceramic material. The substrate 20 may be held on the substrate holder 17 by using an electrostatic charge, a mechanical clamp, a vacuum clamp, or gravity. The substrate 20 on the substrate holder 17 can be heated by applying optical techniques (tungsten filament lamps, lasers), thermal radiation techniques, or by using susceptors and radio frequency (RF) induction heating.

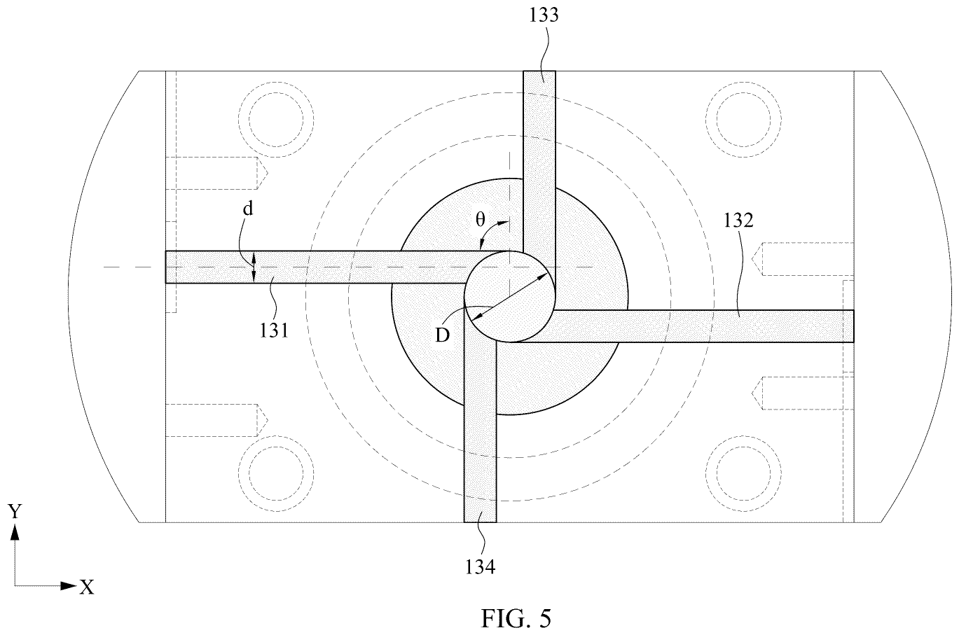

For example, the reactant gasses utilized in oxide deposition include silane (SiH₄) and oxygen (O₂), and the silicon oxide layer is deposited on a surface of the substrate 20, or filling the trenches on the substrate 20. The ratio of the SiH₄ to O₂ can be varied for forming dielectric layers with different properties, such as different index of reflectance. In some embodiments, the SiH₄ is from the first gas source G1, and is introduced into the processing chamber 16 through the first conduit 111, the first inlet 131, the passage 14, and the gas dispenser 15. In some embodiments, the O₂ is from the second gas source G2, and is introduced into the processing chamber 16 through the second conduit 112, the second inlet 132, the passage 14, and the gas dispenser 15. SiH₄ to O₂ are mixed in the passage 14 to generate a downstream gas flowing toward the gas dispenser 15. Alternatively, suitable dopants can be introduced into the processing chamber 16, for example, through another inlet (e.g., 133 or 134 shown in FIG. 5). The deposition reactant gases can use other suitable gases for corresponding deposition process. In some embodiments, the gas dispenser 15 is also connected to a carrier gas supply, such as hydrogen, nitrogen or argon.

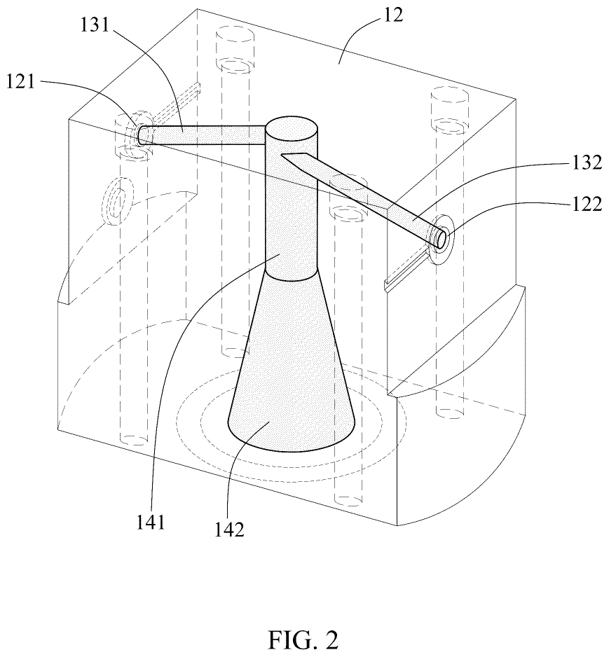

FIG. 2 is a schematic three-dimensional (3D) diagram of the mixer body 12, the inlets 13 and the passage 14 disposed in the mixer body 12 in accordance with some embodiments of the present disclosure. The mixer body 12 can be a cage-like structure. In some embodiments, the mixer body 12 includes a first opening 121 for connection between the first inlet 131 and the first conduit 111 shown in FIG. 1. In some embodiments, the mixer body 12 includes a second opening 122 for connection between the second inlet 132 and the second conduit 112 shown in FIG. 1. Referring back to FIGS. 1 and 2, in some embodiments, each of the inlets 13 elevates from the connection with the respective conduit 11 toward a connecting point of the inlet 13 and the passage 14. In some embodiments, an elevation of the connection of a inlet 13 and its respective conduit 11 is lower than an elevation of the connection of the inlet 13 and the passage 14. In other words, in the embodiments, the first inlet 131 is tilt upward from the first conduit 111, and the second inlet 132 is tilt upward from the second conduit 112. However, the present disclosure is not limited thereto. In other embodiments, the first inlet 131 horizontally extends from the first conduit 111, and the second inlet 132 horizontally extends from the second conduit 112.

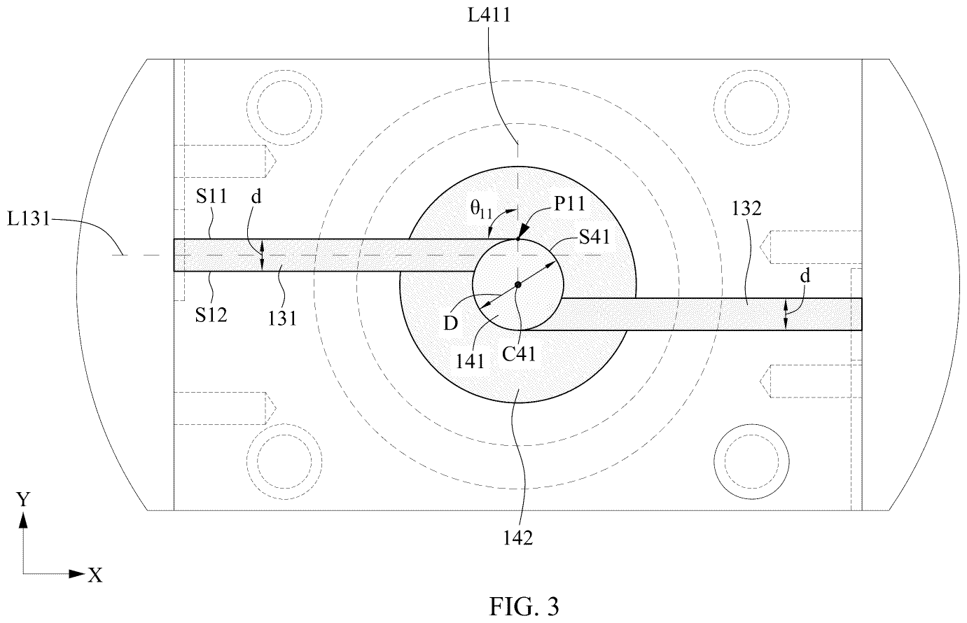

FIG. 3 is a schematic top-view perspective of the mixer body 12 of FIG. 2 in accordance with some embodiments of the present disclosure. As illustrated above, different gases from different gas sources are introduced into the processing chamber through the different inlets 13 and mixed in the passage 14. When two or more gases are mixing, a good disturbing effect and strong cyclone effect generated by the two or more gases in the passage 14 may directly affect a result of deposition or etching. For a purpose of good mixing result of the gases and strong cyclone effect of gas flow, the inlet 13 and the passage 14 together provide a smooth pathway for the gas flow entering the passage 14.

As shown in FIG. 3, each of the inlet 13 may have two opposite to and parallel with sidewalls. In some embodiments, the first inlet 131 has a first sidewall S11 and a second sidewall S12 opposite to and parallel with the first sidewall S11. In some embodiments, the second inlet 132 has a first sidewall S21 and a second sidewall S22 opposite to and parallel with the first sidewall S21. In some embodiments, the upper portion 141 of the passage 14 has a circular configuration from the top view. In some embodiments, the upper portion 141 of the passage 14 has a center C41 and a ring-shaped outer sidewall S41. In some embodiments, the outer sidewall S41 is a curved sidewall.

The first sidewall S11 and the second sidewall S12 of the first inlet 131 individually connects the outer sidewall S41 at different points on the outer sidewall S41 of the upper portion 141 of the passage 14. In some embodiments, the first sidewall S11 of the first inlet 131 contacts the outer sidewall S41 of the upper portion 141 of the passage 14 at a first point P11. In some embodiments, the first inlet 131 extends along a first direction from the top view. For a purpose of illustration, a dashed line labelling L131 indicates a central line of the first inlet 131 is depicted in FIG. 3 for a purpose of showing an extending direction of the first inlet 131; and a dashed line labelling L411 indicates a line connecting the first point P11 and the center C41 of the passage 14. An elevation angle θ11 between the central line L131 of the first inlet 131 and the line L411 is less than or equal to 90±2 degrees and greater than or equal to 10±2 degrees for a purpose of strong cyclone effect of gas flow. It should be noted that, a theoretical range of the elevation angle θ11 of the present disclosure should be 10 to 90 degrees, however, an offset value in a range of −2 to +2 degrees may be presented in a practical application. For a purpose of illustration, the practical offset value is omitted in the following description.

In addition, diameters of the upper portion 141 of the passage 14 and the first inlet 131 can affect a speed of gas flow of the gas and an amount of the gas per unit of time through the first inlet 131. The upper portion 141 of the passage 14 has a diameter D, and the first inlet 131 has a diameter d. In some embodiments, the diameter D of the upper portion 141 is greater than the diameter d of the first inlet 131. In some embodiments, a ratio D/d of the diameter D of the upper portion 141 to the diameter d of the first inlet 131 is in a range of 1.7 to 5.4. In some embodiments, the diameter D of the upper portion 141 is at least twice of the diameter d of the first inlet 131. In some embodiments, the diameter D of the upper portion 141 of the passage 14 is in a range of 8 to 20 millimeters (mm). In some embodiments, the diameter d of the first inlet 131 is in a range of 4 to 8 mm.

All of the inlets 13 may have substantially equal diameters d for a purpose of ease of design of the apparatus. In some embodiments, a diameter of the second inlet 132 is substantially equal to the diameter d of the first inlet 131. Alternatively, different the inlets 13 can have different diameters according to different gases used in the operation for a purpose of flexibility of design of the amount and speed of gas flow. In some embodiments, the diameter of the second inlet 132 is different from the diameter d of the first inlet 131. The diameter of the second inlet 132 can be greater than or smaller than the diameter d of the first inlet 131. In some embodiments, the diameter of the second inlet 132 is in a range of 4 to 8 mm. For a purpose of ease of illustration, in the following description, the embodiments having multiple inlets 13 with substantially equal diameters are used as exemplary embodiments. However, it is not intended to limit the present disclosure.

As shown in FIG. 3, the first sidewall S21 and the second sidewall S22 of the first inlet 131 individually connects the outer sidewall S41 at different points on the outer sidewall S41 of the upper portion 141 of the passage 14. Similarly, an elevation angle between a central line of the second inlet 132 and a line connecting a contact point of the first sidewall S21 on the outer sidewall S41 and the center C41 of the upper portion 141 is less than or equal to 90 degrees for a purpose of strong cyclone effect of gas flow. In some embodiments, the elevation angle between a central line of the second inlet 132 and a line connecting a contact point of the first sidewall S21 on the outer sidewall S41 and the center C41 of the upper portion 141 is in a range of 10 to 90 degrees.

In some embodiments shown in FIG. 3, for a purpose of good disturbing effect, each of the diameters of the first inlet 131 and the second inlet 132 are less than a half of the diameter D of the upper portion 141 of the passage 14. In some embodiments, the first inlet 131 and the second inlet 132 extends along a same direction but separated from each other along the direction as shown in FIG. 3.

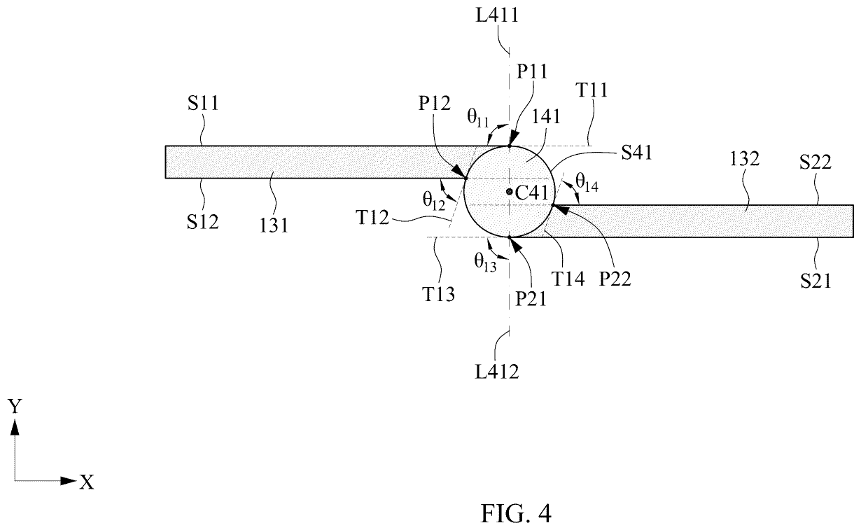

FIG. 4 is a schematic top-view perspective of the upper portion 141 of the passage 14 and the inlets 13 (including 131 and 132) in accordance with some embodiments of the present disclosure. As illustrated above in FIG. 3, the elevation angle θ11 between the central line L131 of the first inlet 131 and the line L411 is in a range of 10 to 90 degrees for a purpose of strong cyclone effect of gas flow. In some embodiments, the first sidewall S11 and the second sidewall S12 of the first inlet 131 are substantially parallel. In other words, an angle between the first sidewall S11 and the line L411 is substantially equal to the elevation angle θ11, which is in a range of 10 to 90 degrees. In some embodiments, the first sidewall S11 and the line L411 are substantially perpendicular. In some embodiments, the first sidewall S11 is substantially parallel with a tangent line T11 (indicated by a dashed line) at the first point P11 on the outer sidewall S41. In some embodiments, an angle between the first sidewall S11 and the tangent line T11, which is a complementary angle of the elevation angle θ11, is in a range of 0 to 80 degrees. In some embodiments as shown in FIG. 4, the elevation angle θ11 is about 90 degrees. In other word, an angle between the first sidewall S11 and the tangent line T11 is about zero degrees. In some embodiments, the second sidewall S12 of the first inlet 131 contacts the outer sidewall S41 of the upper portion 141 of the passage 14 at a second point P12. In some embodiments, an elevation angle θ12 between the second sidewall S12 and a tangent line T12 (indicated by a dashed line) at the second point P12 on the outer sidewall S41 is less than or equal to 90 degrees. In some embodiments, the elevation angle θ12 is greater than the angle between the first sidewall S11 and the tangent line T11.

Similarly, the first sidewall S21 and the second sidewall S22 of the second inlet 132 individually connects the outer sidewall S41 at different points on the outer sidewall S41 of the upper portion 141 of the passage 14. In some embodiments, the first sidewall S21 of the second inlet 132 contacts the outer sidewall S41 of the upper portion 141 of the passage 14 at a third point P21. In some embodiments, the second inlet 132 extends along the first direction from the top view. In some embodiments, the second inlet 132 is substantially parallel with the first inlet 131. For a purpose of illustration, a dashed line labelling L412 indicates a line connecting the third point P21 and the center C41 of the passage 14. An elevation angle θ13 between the first sidewall S21 of the second inlet 132 and the line L412 is in a range of 10 to 90 degrees for a purpose of strong cyclone effect of gas flow. Since the first sidewall S21 and the second sidewall S22 are substantially parallel, a central line (not shown) of the second inlet 132 should be substantially parallel with the first sidewall S21 of the second inlet 132. In some embodiments, an angle between the central line of the second inlet 132 and the line L412 is in a range of 10 to 90 degrees for a purpose of strong cyclone effect of gas flow.

In some embodiments, the first sidewall S21 and the line L412 are substantially perpendicular. In some embodiments, the first sidewall S21 is substantially parallel with a tangent line T13 (indicated by a dashed line) at the third point P21 on the outer sidewall S41. In some embodiments, the second sidewall S22 of the second inlet 132 contacts the outer sidewall S41 of the upper portion 141 of the passage 14 at a fourth point P22. In some embodiments, an elevation angle θ14 between the second sidewall S22 and a tangent line T14 (indicated by a dashed line) at the fourth point P22 on the outer sidewall S41 is in a range of 10 to 90 degrees.

The above figures (FIGS. 1 to 4) show the apparatus includes two inlets 131 and 132. It should be noted that a number of the inlets 13 can be adjusted according to a total number of gas sources required for different applications. As illustrated above, the elevation angle θ11 is in a range of 10 to 90 degrees, and a complementary angle of the elevation angle θ11 is in a range of 0 to 80 degrees.

FIG. 5 is a schematic top-view perspective of the upper portion 141 of the passage 14 and four inlets 13 in accordance with some embodiments of the present disclosure. In some embodiments, the inlets 13 further includes a third inlet 133 and a fourth inlet 134. In some embodiments, the inlets 131, 132, 133 and 134 connects to different gas or fluid sources respectively. In some embodiments, the inlets 131 and 132 are disposed on two opposite sides of the upper portion 141 of the passage 14. In some embodiments, the inlets 133 and 134 are disposed between the inlets 131 and 132. In some embodiments, the inlets 131 and 132 are disposed on two opposite sides of the upper portion 141 of the passage 14. Positional relationship between each of the inlets 131, 132, 133 and 134 and the outer sidewall S41 of the upper portion 141 of the passage 14 can be referred to the positional relationship between the first inlets 131 and the outer sidewall S41 of the upper portion 141 of the passage 14 as depicted in FIGS. 3 and 4. Repeated illustration is omitted herein.

FIG. 5 is for a purpose of illustration but not intended to limit the present disclosure. As illustrated above, the diameters D and d shown in FIG. 3 can affect a speed of gas flow toward the substrate 20 and an amount of a gas source per unit of time through the respective inlet. In some embodiments, a total number of the inlets 13 is in a range of 2 to 7. In some embodiments, the angle between an inlet and a line connecting the center C41 and a contacting point of the respective inlet is in a range of 10 to 90 degrees.

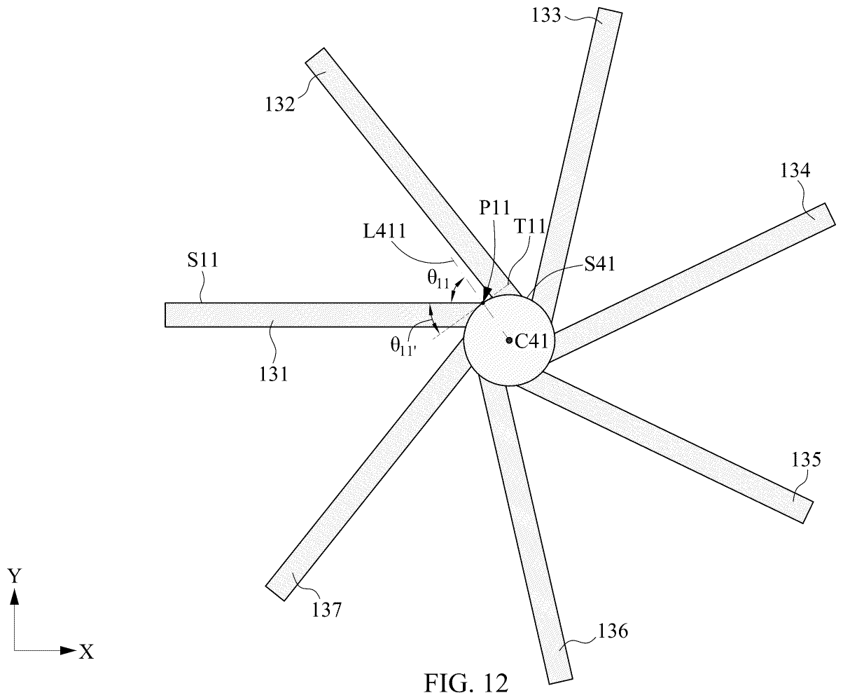

FIG. 12 is a schematic top-view perspective of the upper portion 141 of the passage 14 and seven inlets 13 in accordance with some embodiments of the present disclosure. In some embodiments, the inlets 13 includes seven inlents 131 to 137 as shown in FIG. 12. In some embodiments, the inlets 131 to 137 connects to different gas or fluid sources respectively. In some embodiments, the inlets 131 to 137 are evenly distributed around the upper portion 141. In some embodiments, the first inlet 131 of the seven inlets 13 has a first sidewall S11 contacts an outer sidewall S41 of the upper portion 141 at the first point P11. A dashed line labelling L411 indicates a line connecting the first point P11 and a center C41 of the upper portion 141 of the passage 14. An elevation angle θ11 between the first sidewall S11 and the line L411 is in a range of 10 to 90 degrees for a purpose of strong cyclone effect of gas flow. In other word, an elevation angle θ11′, which is a complementary angle of the elevation angle θ11, between a tangent line T11 at the first point P11 on the outer sidewall S41 and the first sidewall S11 should be 90 degrees minus the elevation angle θ11. In some embodiments, the elevation angle θ11′ is in a range of 0 to 80 degrees. As shown in FIG. 12, in some embodiments, the elevation angle θ11 is less than 90 degrees. In some embodiments, the inlets 131 to 137 may have substantially equal diameters. In some embodiments, the elevation angle θ11′ is greater than zero degrees. In some embodiments, the inlets 132 to 137 or may have similar or substantially equal elevation angle between a sidewall and a line connecting a contacting point of the sidewall and the center C41, and repeated description is omitted herein for a purpose of brevity.

The present disclosure further provides a method of film deposition or etching operation using the apparatus as illustrated above. Therefore, a method 700 is provided.

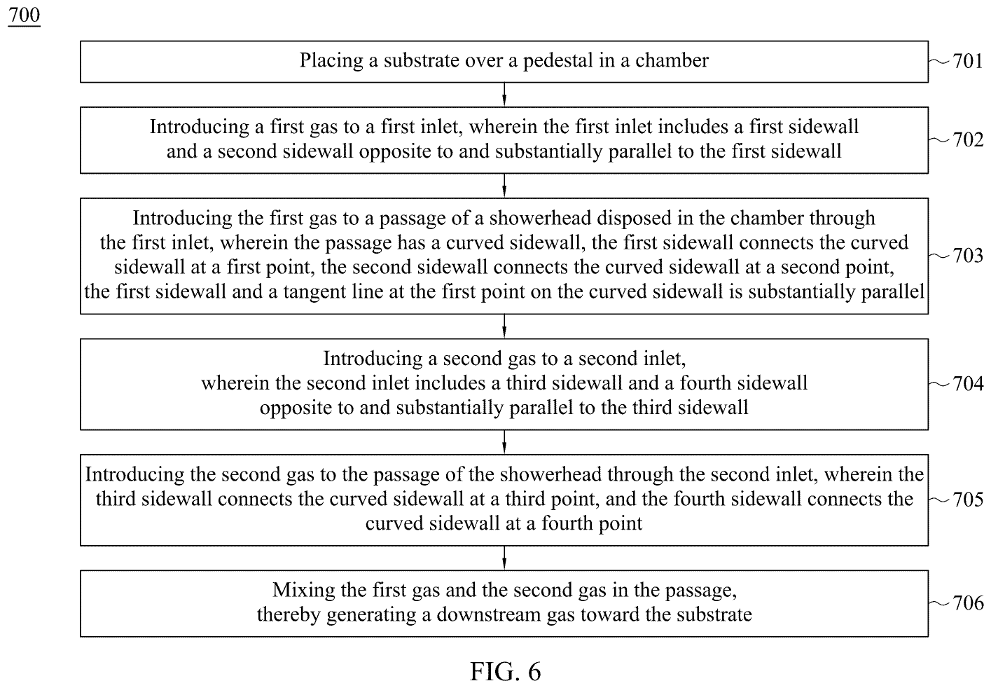

Referring back to FIG. 6, FIG. 6 is a flow diagram of the method 700 for manufacturing a semiconductor structure in accordance with some embodiments of the present disclosure. The method 700 includes a number of operations (701, 702, 703, 704, 705 and 706), and the description and illustration are not deemed as a limitation to the sequence of the operations. In the operation 701, a substrate is placed over a pedestal in a chamber. In the operation 702, a first gas is introduced to a first inlet, wherein the first inlet includes a first sidewall and a second sidewall opposite to and substantially parallel to the first sidewall. In the operation 703, the first gas is introduced to a passage of a showerhead disposed in the chamber through the first inlet, wherein the passage has a curved sidewall, the first sidewall connects the curved sidewall at a first point, the second sidewall connects the curved sidewall at a second point, the first sidewall and a tangent line at the first point on the curved sidewall is substantially parallel. In the operation 704, a second gas is introduced to a second inlet, wherein the second inlet includes a third sidewall and a fourth sidewall opposite to and substantially parallel to the third sidewall. In the operation 705, the second gas is introduced to the passage of the showerhead through the second inlet, wherein the third sidewall connects the curved sidewall at a third point, and the fourth sidewall connects the curved sidewall at a fourth point. In the operation 706, the first gas and the second gas are mixed in the passage, thereby generating a downstream gas toward the substrate.

The operations of the method 700 can be rearranged or otherwise modified within the scope of the various aspects. In some embodiments, additional processes are provided before, during, and after the method 700, and some other processes are only briefly described herein. Thus, other implementations are possible within the scope of the various aspects described herein.

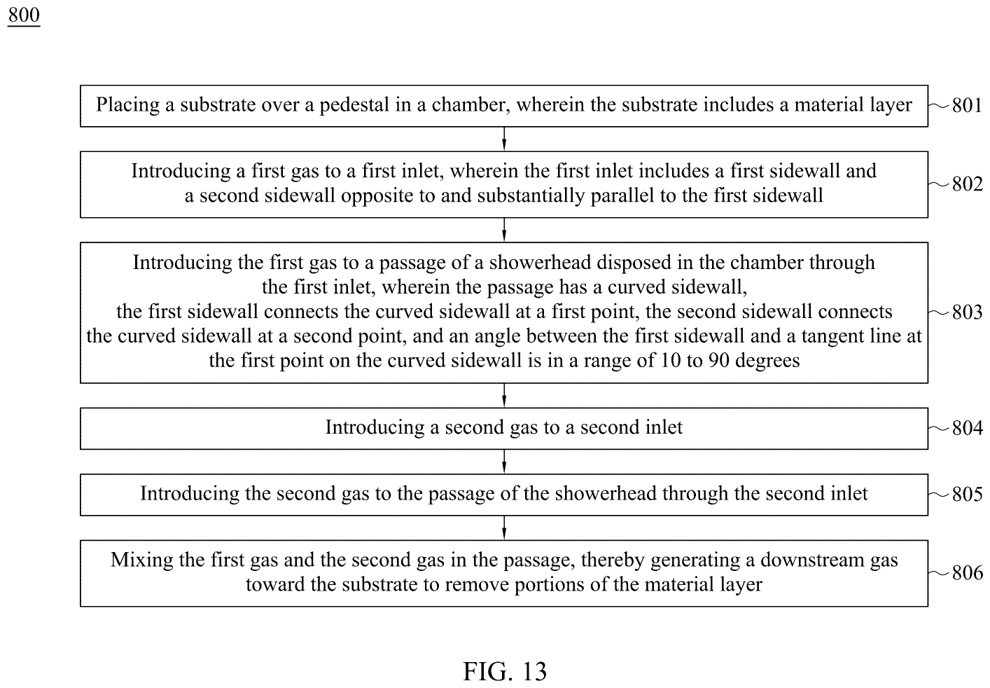

In some embodiments, the apparatus is applied in an etching operation. FIG. 13 is a flow diagram of the method 800 for manufacturing a semiconductor structure in accordance with some embodiments of the present disclosure. The method 800 includes a number of operations (801, 802, 803, 804, 805 and 806), and the description and illustration are not deemed as a limitation to the sequence of the operations. In the operation 801, a substrate is placed over a pedestal in a chamber, wherein the substrate includes a material layer thereon. In the operation 802, a first gas is introduced to a first inlet, wherein the first inlet includes a first sidewall and a second sidewall opposite to and substantially parallel to the first sidewall. In the operation 803, the first gas is introduced to a passage of a showerhead disposed in the chamber through the first inlet, wherein the passage has a curved sidewall, the first sidewall connects the curved sidewall at a first point, the second sidewall connects the curved sidewall at a second point, and an angle between the first sidewall and a tangent line at the first point on the curved sidewall is in a range of 10 to 90 degrees. In the operation 804, a second gas is introduced to a second inlet. In the operation 805, the second gas is introduced to the passage of the showerhead through the second inlet. In the operation 806, the first gas and the second gas are mixed in the passage, thereby generating a downstream gas toward the substrate to remove portions of the material layer.

Therefore, the present disclosure provides an apparatus including an inlet having both sidewalls contacting a passage of a mixer body. In addition, for a purpose of strong cyclone effect, the inlet has one of the sidewalls being substantially parallel to a tangent line of at the contacting point of the inlet on the passage. A strong cyclone effect of different gas flow can be provided in the passage, and therefore a result of mixing different gases can be achieve. Comparing a film deposited on a substrate using the apparatus of the present disclosure with a film formed using another apparatus having the inlets with each of them have only one sidewall contacting the passage, a thickness uniformity across the substrate of the present disclosure can be improved by 60% compared to the other apparatus. In some embodiments, a thickness variation across a substrate of a film formed by the method 700 shown in FIG. 6 can be controlled within 2 angstroms.

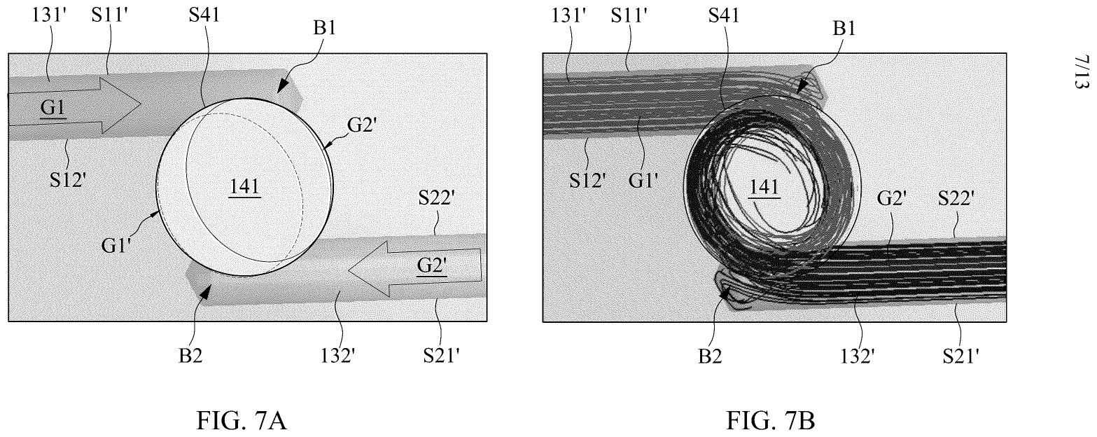

Referring back to FIGS. 7A and 7B are schematic diagrams of a comparative embodiment. The comparative embodiments includes a first inlet 131′ and a second inlet 132′ connecting to an upper portion 141 of a passage 14. The upper portion 141 of the passage 14 of the comparative embodiment can be identical to the upper portion 141 of the passage 14 as illustrated above in FIGS. 1 to 4, and repeated description is omitted herein. The first inlet 131′ and the second inlet 132′ of the comparative embodiment can be similar to the first inlet 131 and the second inlet 132 as illustrated in FIGS. 1 to 4 above, except that each of the first inlet 131′ and the second inlet 132′ has only one sidewall connecting the upper portion 141 of the passage 14. For example, the first inlet 131′ includes two opposite sidewalls S11′ and S12′, the sidewall S12′ connects an outer sidewall S41 of the upper portion 141, but the sidewall S11′ is separated from the outer sidewall S41 of the upper portion 141. In addition, the second inlet 132′ includes two opposite sidewalls S21′ and S22′, the sidewall S22′ connects the outer sidewall S41 of the upper portion 141, but the sidewall S21′ is separated from the outer sidewall S41 of the upper portion 141.

As shown in FIGS. 7A and 7B, a space between the sidewall S11′ and the outer sidewall S41 proximal to an end of the sidewall S11′ becomes a blocking area B1 to a first gas G1′, which introduced into the upper portion 141 through the first inlet 131′; and a space between the sidewall S21′ and the outer sidewall S41 proximal to an end of the sidewall S21′ becomes a blocking area B2 to a second gas G2′, which introduced into the upper portion 141 through the first inlet 131′. The blocking area B1 may result in reductions of speed and kinetic energy of the first gas G1′, and similarly, the blocking area B2 may result in reductions of speed and kinetic energy of the second gas G2′. Therefore, a strength of cyclone effect of the first gas G1′ and the second gas G2′ can be reduced. FIG. 7A shows a main area of gas flow of the first gas G1′ indicated by a dotted circle labelling G1′, and a main area of gas flow of the second gas G2′ indicated by a dotted circle labelling G2′. It shows gas flows of the first gas G1′ and the second gas G2′ are not entirely overlapped. FIG. 7B is a schematic diagram showing a simulation result of gas flows of the first gas G1′ and the second gas G2′ of the comparative embodiment.

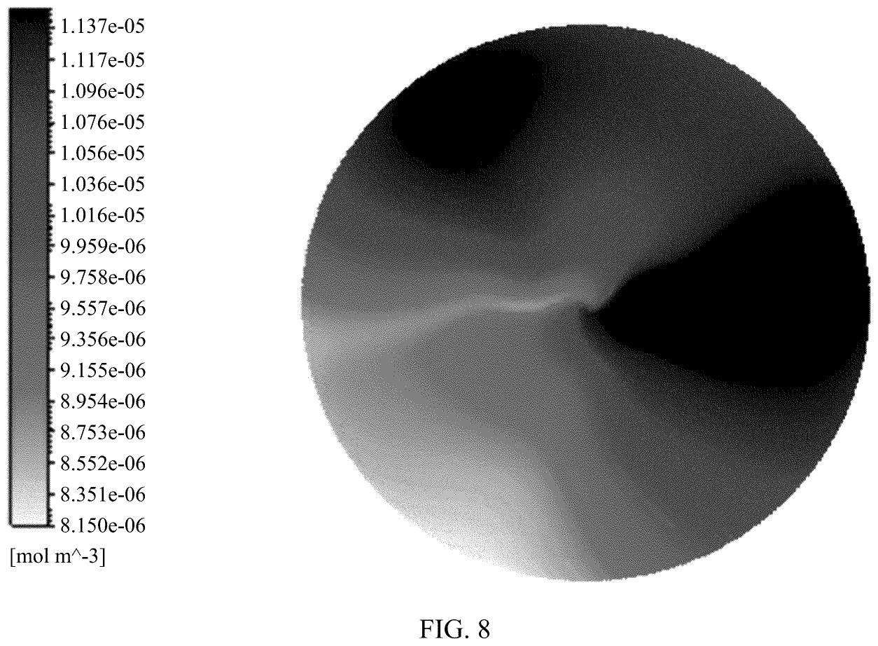

FIG. 8 is a schematic diagram showing distribution of gas concentrations of one of the first gas G1′ and the second gas G2′ in the passage 14 of the comparative embodiment of FIGS. 7A and 7B. For example, FIG. 8 shows a gas concentration of the first gas G1′ in the passage 14 at a certain time point during the operation. Due to the presence of the blocking area B1 shown in FIGS. 7A and 7B, the first gas G1′ is unevenly distributed in the passage 14, and it may result in a worse thickness uniformity of a film formed thereof.

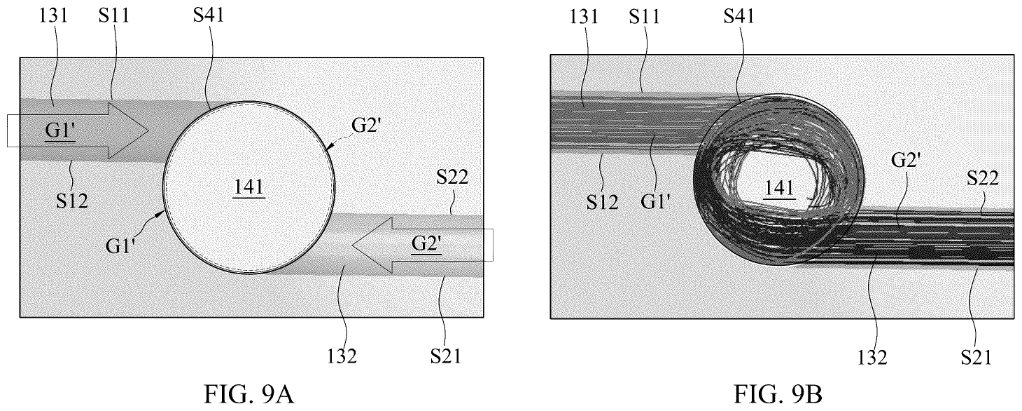

FIGS. 9A and 9B are schematic diagrams in accordance with one embodiment of the present disclosure, wherein FIG. 9A shows main areas of gas flows of a first gas G1′ and a second gas G2′ in an upper portion 141 of a passage 14, and FIG. 9B is a schematic diagram showing a simulation result of the gas flows of the first gas G1′ and the second gas G2′ of the embodiment. As shown in FIGS. 9A and 9B, the first inlet 131 and the passage 14 together provide a smooth pathway for the gas flow of the first gas G1′ entering the passage 14, and the second inlet 132 and the passage 14 together provide a smooth pathway for the gas flow of the second gas G2′ entering the passage 14. The gas flows of the first gas G1′ and the second gas G2′ are entirely overlapped. In addition, a sidewall S11 of the first inlet 131 is substantially parallel to a tangent line of a contacting point of the sidewall S11 and an outer sidewall S41 of the upper portion 141, and thus the main area of the gas flow of the first gas G1′ can cover substantially an entirety of inner space of the upper portion 141. A sidewall S21 of the second inlet 132 is substantially parallel to a tangent line of a contacting point of the sidewall S21 and the outer sidewall S41 of the upper portion 141, and thus the main area of the gas flow of the first gas G1′ can cover substantially an entirety of inner space of the upper portion 141. Therefore, a strong cyclone effect can be achieved.

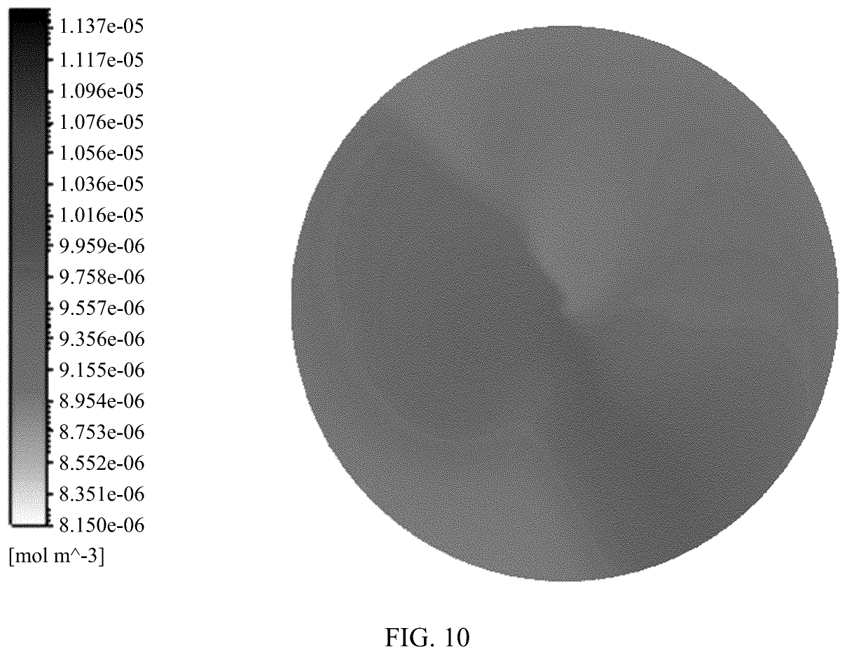

FIG. 10 is a schematic diagram showing gas concentration of one of the first gas G1′ and the second gas G2′ in the passage 14 of the embodiment of FIGS. 9A and 9B. For example, FIG. 10 shows a gas concentration of the first gas G1′ in the passage 14 at a certain time point during the operation. Due to absence of the blocking area B1 shown in FIGS. 7A and 7B, the first gas G1′ is evenly distributed in the passage 14, and a thickness uniformity of a film formed thereof can be thereby improved.

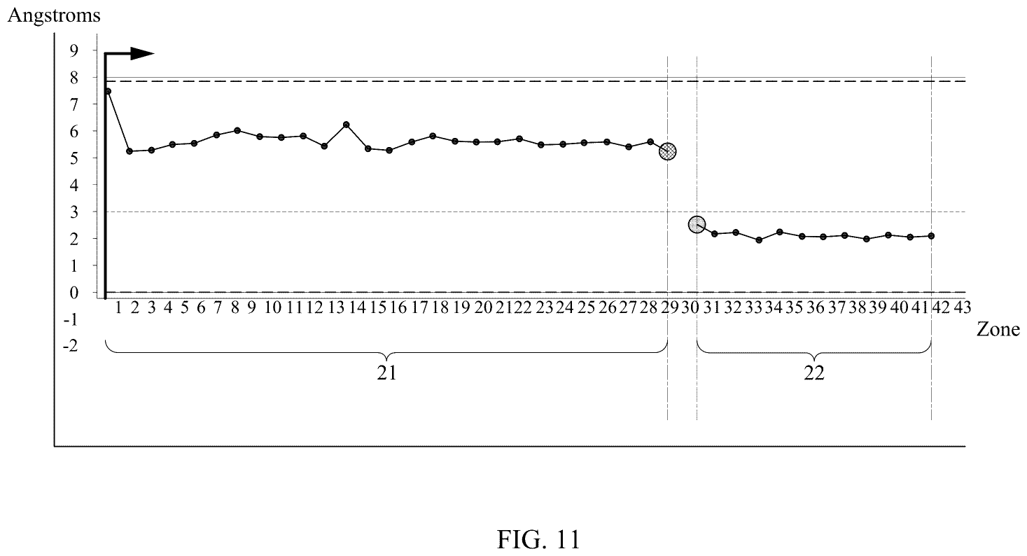

FIG. 11 is a schematic line chart showing thickness differences between different points of a plurality of first films 21 formed by the comparative embodiments shown in FIGS. 7A and 7B, and thickness differences between different points of a plurality of second films 22 formed by the embodiment shown in FIGS. 9A and 9B. Thickness measurements are provided on each of the first films 21 and each of the second films 22. In some embodiments, 10 points of a film 21 or 22 on a substrate are measured for thicknesses of the film at the corresponding points. Each dot on the line chart shown in FIG. 11 represents a maximum value of thickness differences among the 10 points measured by the thickness measurement, and each of the first films 21 and each of the second films 22 are measured. As shown in FIG. 11, the first films 21 have an average thickness variation about 5 angstroms, and the second films 22 have an average thickness variation about 2 angstroms. It shows an improvement in thickness uniformity by about 60%.

In accordance with some embodiments of the disclosure, an apparatus for performing a film deposition or an etching operation is provided. The apparatus includes a chamber; a substrate holder, disposed in the chamber, and configured to hold a substrate during the film deposition; a gas dispenser, disposed in the chamber and above the substrate holder; a passage, disposed above and connecting to the gas dispenser, wherein the passage has a curved sidewall; and a first inlet, connecting to the passage for a first gas injection to the gas dispenser, wherein the first inlet includes a first sidewall and a second sidewall opposite to and substantially parallel to the first sidewall, the first sidewall connects the curved sidewall at a first point, the second sidewall connects the curved sidewall at a second point, the first sidewall and a first tangent line at the first point on the curved sidewall is in a range of 0 to 80 degrees.

In accordance with some embodiments of the disclosure, an apparatus is provided. The apparatus includes a gas mixer body, disposed over a chamber for the film deposition; a first inlet, connecting to a first gas source and extending into the gas mixer body for a first gas injection, wherein the first inlet includes a first sidewall and a second sidewall opposite to and substantially parallel to the first sidewall; a passage, disposed in the gas mixer body and connecting the first inlet and the chamber, wherein the passage has an outer sidewall, the first sidewall connects the outer sidewall at a first tangent point, the second sidewall connects the outer sidewall at a second tangent point, the first sidewall and a first tangent line at the first tangent point on the outer sidewall is in a range of 0 to 80 degrees; and a second inlet, connecting to a second gas source and extending into the gas mixer body for a second gas injection, wherein the second inlet includes a third sidewall and a fourth sidewall opposite to and substantially parallel to the third sidewall, the third sidewall connects the outer sidewall at a third tangent point, the fourth sidewall connects the outer sidewall at a fourth tangent point, the third sidewall and a third tangent line at the third tangent point on the outer sidewall is in a range of 0 to 80 degrees.

In accordance with some embodiments of the disclosure, a method of film deposition is provided. The method may include several operations. A substrate is placed over a pedestal in a chamber. A first gas is introduced to a first inlet, wherein the first inlet includes a first sidewall and a second sidewall opposite to and substantially parallel to the first sidewall. The first gas is introduced to a passage of a showerhead disposed in the chamber through the first inlet, wherein the passage has a curved sidewall, the first sidewall connects the curved sidewall at a first point, the second sidewall connects the curved sidewall at a second point, the first sidewall and a tangent line at the first point on the curved sidewall is in a range of 0 to 80 degrees. A second gas is introduced to a second inlet, wherein the second inlet includes a third sidewall and a fourth sidewall opposite to and substantially parallel to the third sidewall. The second gas is introduced to the passage of the showerhead through the second inlet, wherein the third sidewall connects the curved sidewall at a third point, and the fourth sidewall connects the curved sidewall at a fourth point. The first gas and the second gas are mixed in the passage, thereby generating a downstream gas toward the substrate.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An apparatus for film deposition, comprising:
a chamber;
a substrate holder, disposed in the chamber, and configured to hold a substrate during the film deposition;
a gas dispenser, disposed in the chamber and above the substrate holder;
a passage, disposed above and connecting to the substrate holder, wherein the passage has a curved sidewall; and
a first inlet, connecting to the passage for a first gas injection to the gas dispenser, wherein the first inlet includes a first sidewall and a second sidewall opposite to and substantially parallel to the first sidewall, the first sidewall connects the curved sidewall at a first point, the second sidewall connects the curved sidewall at a second point, and a first angle between the first sidewall and a first tangent line at the first point on the curved sidewall is in a range of 0 to 80 degrees.

2. The apparatus of claim 1, wherein a second angle between the second sidewall and a second tangent line at the second point is less than or equal to 90 degrees.

3. The apparatus of claim 1, wherein the first sidewall is aligned with the first tangent line at the first point.

4. The apparatus of claim 1, further comprising:
a second inlet, connecting to the passage for a second gas injection to the gas dispenser, wherein the second inlet includes a third sidewall and a fourth sidewall opposite to and substantially parallel to the third sidewall, the third sidewall connects the curved sidewall at a third point, the fourth sidewall connects the curved sidewall at a fourth point, the third sidewall and a third tangent line at the third point on the curved sidewall is in a range of 0 to 80 degrees.

5. The apparatus of claim 4, wherein a second angle between the fourth sidewall and a fourth tangent line at the fourth point is less than or equal to 90 degrees.

6. The apparatus of claim 4, wherein the third sidewall is substantially parallel to with the first sidewall.

7. The apparatus of claim 1, wherein the first inlet is one of a plurality of inlets, each inlet has a sidewall contacting the curved sidewall of the passage at a contacting point, the sidewall of each inlet and a tangent line at the contacting point of the sidewall on the curved sidewall is substantially parallel.

8. The apparatus of claim 7, wherein a number of the plurality of inlets is in a range of 2 to 7.

9. An apparatus for film deposition, comprising:
a gas mixer body, disposed over a chamber for the film deposition;
a first inlet, connecting to a first gas source and extending into the gas mixer body for a first gas injection, wherein the first inlet includes a first sidewall and a second sidewall opposite to and substantially parallel to the first sidewall;
a passage, disposed in the gas mixer body and connecting the first inlet and the chamber, wherein the passage has an outer sidewall, the first sidewall connects the outer sidewall at a first tangent point, the second sidewall connects the outer sidewall at a second tangent point, the first sidewall and a first tangent line at the first tangent point on the outer sidewall is in a range of 0 to 80 degrees; and
a second inlet, connecting to a second gas source and extending into the gas mixer body for a second gas injection, wherein the second inlet includes a third sidewall and a fourth sidewall opposite to and substantially parallel to the third sidewall, the third sidewall connects the outer sidewall at a third tangent point, the fourth sidewall connects the outer sidewall at a fourth tangent point, the third sidewall and a third tangent line at the third tangent point on the outer sidewall is in a range of 0 to 80 degrees.

10. The apparatus of claim 9, wherein a first angle between the first sidewall and a first line connecting the first tangent point and a center of the passage is less than or substantially equal to 90 degrees.

11. The apparatus of claim 9, wherein a second angle between the third sidewall and a second line connecting the second tangent point and a center of the passage is less than or substantially equal to 90 degrees.

12. The apparatus of claim 9, wherein a ratio between a diameter of the passage and a diameter of the first inlet is in a range of 1.7 to 5.4.

13. The apparatus of claim 9, wherein a diameter of the first inlet is substantially equal to a diameter of the second inlet.

14. The apparatus of claim 9, wherein the first sidewall is substantially parallel to the third sidewall.

15. The apparatus of claim 9, wherein the first inlet extends along a first direction, the second inlet extends along the first direction, and the first inlet and the second inlet are separated along the first direction.

16. The apparatus of claim 9, further comprising:
a gas dispenser, disposed below the gas mixer body in the chamber, wherein the passage connects to the gas dispenser for introducing a mixed gas of the first gas injection and the second gas injection to the chamber.

17. A method of film deposition, comprising:
placing a substrate over a pedestal in a chamber;
introducing a first gas to a first inlet, wherein the first inlet includes a first sidewall and a second sidewall opposite to and substantially parallel to the first sidewall;
introducing the first gas to a passage through the first inlet, wherein the passage has a curved sidewall, the first sidewall connects the curved sidewall at a first point, the second sidewall connects the curved sidewall at a second point, the first sidewall and a tangent line at the first point on the curved sidewall is substantially parallel;
introducing a second gas to a second inlet, wherein the second inlet includes a third sidewall and a fourth sidewall opposite to and substantially parallel to the third sidewall;
introducing the second gas to the passage through the second inlet, wherein the third sidewall connects the curved sidewall at a third point, and the fourth sidewall connects the curved sidewall at a fourth point; and
mixing the first gas and the second gas in the passage, thereby generating a downstream gas toward the substrate.

18. The method of claim 17, wherein the first gas and the second gas are different from each other.

19. The method of claim 17, further comprising:
distributing the downstream gas from the passage toward the substrate through a gas dispenser disposed over the substrate in the chamber.

20. The method of claim 17, further comprising:
forming a film over the substrate, wherein a thickness variation of the film across the substrate is less than or equal to 2 angstroms.
